(19) United States
(12) Patent Application Publication
(10) Pub. No.: US 2025/0308934 A1
(43) Pub. Date: Oct. 2, 2025

(54) SELECTIVE DEFLASH PROCESS FOR LEAD FRAMES

(71) Applicant: Texas Instruments Incorporated, Dallas, TX (US)

(72) Inventors: Easwaran AL Sivakumar, Klang (MY); Shu Hui Ooi, Ayer Keroh (MY); Kian Khee Lim, Melaka (MY); Parthiben Kumaran, Tampin (MY)

(21) Appl. No.: 18/622,966

(22) Filed: Mar. 31, 2024

(51) Int. Cl. H01L 21/48; H01L 21/56; H01L 23/495

(52) U.S. Cl. CPC H01L 21/485; H01L 21/4864; H01L 21/565; H01L 23/4951; H01L 23/49575

(57) ABSTRACT

A semiconductor package includes a lead having an exterior surface portion, at an exterior of the semiconductor package, and an encapsulated surface portion contacting an encapsulation material. A solderable metal layer is on the exterior surface portion. The lead has a higher surface roughness at the encapsulated surface portion than at the exterior surface portion. Before the solderable metal layer is formed, polymer material of the encapsulation material may extend onto the exterior surface portion. A first portion of the polymer material on the exterior surface portion is removed, exposing areas of the lead. Metal from the lead, where exposed by a remaining portion of the polymer material, is removed by an electrolytic process. The lead is biased to a positive potential with respect to an electrolytic solution. Subsequently, the remaining portion of the polymer material is removed. The solderable metal layer is formed on the exterior surface portion.

### TECHNICAL FIELD

This disclosure relates to the field of semiconductor packages. More particularly, but not exclusively, this disclosure relates to lead frames in semiconductor packages.

### BACKGROUND

Some semiconductor packages use encapsulation material having a polymer material on lead frames to surround and protect the semiconductor die. The encapsulation material is commonly applied to the die and lead frame by a molding process using mold plates. During the molding process, small amounts of the polymer material may leak out under the pressure, resulting in an unwanted mold flash on the lead frame. Mold flash is sometimes referred to as mold leak, resin bleed, or epoxy bleed. Deflashing, that is, removing the mold flash, is an important step during the production stage in the semiconductor industry.

### SUMMARY

The present disclosure introduces a semiconductor package including a lead. A surface of the lead is divided into an exterior surface portion, located at an exterior of the semiconductor package, and an encapsulated surface portion. The semiconductor package includes a solderable metal layer on the exterior surface portion. The lead has a higher surface roughness at the encapsulated surface portion than at the exterior surface portion under the solderable metal layer. The semiconductor package includes a semiconductor die electrically connected to the encapsulated surface portion of the lead. The semiconductor package includes an encapsulation material contacting the semiconductor die and contacting the encapsulated surface portion of the lead. The encapsulation material is electrically non-conductive and includes a polymer material. The solderable metal layer is on the exterior surface portion of the lead at the exterior of the semiconductor package.

The polymer material may extend onto the exterior surface portion of the lead, before the solderable metal layer is formed. The semiconductor package is formed by a process including removing a first portion of the polymer material on the exterior surface portion of the lead. Subsequently, a portion of the lead, where exposed by a remaining portion of the polymer material, is removed by an electrolytic process. The electrolytic process includes biasing the lead to a positive potential with respect to an electrolytic solution contacting the exterior surface portion of the lead. Subsequently, the remaining portion of the polymer material is removed from the exterior surface portion. The solderable metal layer is formed on the exterior surface portion of the lead after the remaining portion of the polymer material is removed.

### BRIEF DESCRIPTION OF THE VIEWS OF THE DRAWINGS

FIG. 1A through FIG. 1K are perspectives and cross sections of an example semiconductor package, depicted in stages of an example method of formation.

FIG. 2 is a current voltage graph for an example selective descaling process.

FIG. 3A through FIG. 3F are cross sections and a perspective of another example semiconductor package, depicted in stages of another example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

A semiconductor package includes a lead. The lead may be one of a plurality of leads of the semiconductor package. A surface of the lead is divided into an encapsulated surface portion and an exterior surface portion. The semiconductor package includes a solderable metal layer on the exterior surface portion of the lead. The lead has a higher surface roughness at the encapsulated surface portion than at the exterior surface portion. Surface roughness may be measured by various methods, including surface profilometry, optical profilometry, and atomic force microscopy, by way of example. Surface roughness may be expressed by any of several parameters. One surface roughness parameter is Ra, which is an arithmetic average of surface heights measured across the lead. Another surface roughness parameter is Rrms, which is a root mean square (rms) value of peaks and valleys across the lead.

The semiconductor package includes a semiconductor die electrically connected to the encapsulated surface portion of the lead. The semiconductor package includes an encapsulation material contacting the semiconductor die and contacting the encapsulated surface portion of the lead. The encapsulation material is electrically non-conductive and includes a polymer material. The solderable metal layer is exposed at an exterior of the semiconductor package.

The lead may have a roughened surface, as a result of etching or of plating bumps. The roughened surface may improve adhesion of the encapsulation material to the lead. After the encapsulation material is formed on the semiconductor die and the encapsulated surface portion of the lead, there may be unwanted polymer material of the encapsulation material, that is, mold flash, on the exterior surface portion of the lead. The semiconductor package is formed by a process that includes steps to remove the polymer material, partially or completely. The steps to remove the polymer material include removing a first portion of the polymer material on the exterior surface portion of the lead. Areas of the lead at the exterior surface are exposed by a remaining portion of the polymer material. Subsequently, a portion of the lead, exposed by the remaining portion of the polymer material, is removed by an electrolytic process. The electrolytic process includes biasing the lead to a positive potential with respect to an electrolytic solution contacting the exterior surface portion of the lead. Subsequently, the remaining portion of the polymer material is removed from the exterior surface portion. The solderable metal layer is subsequently formed on the exterior surface portion.

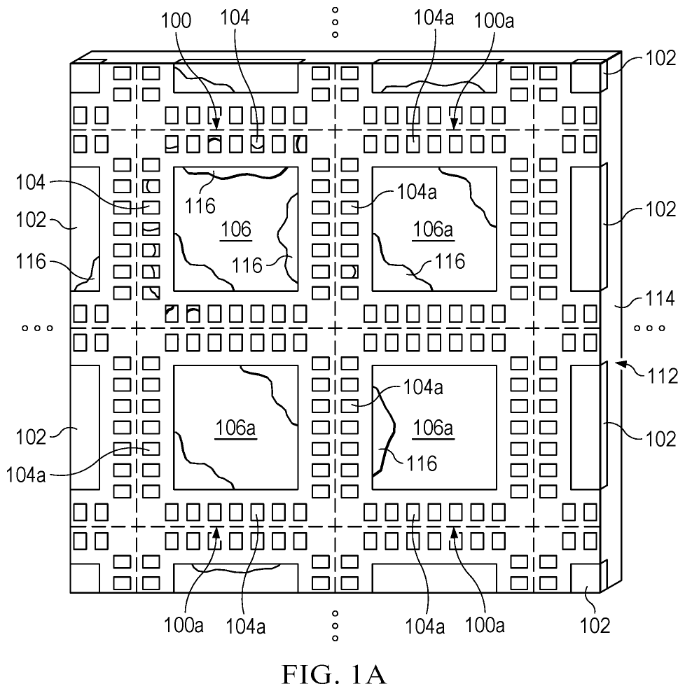

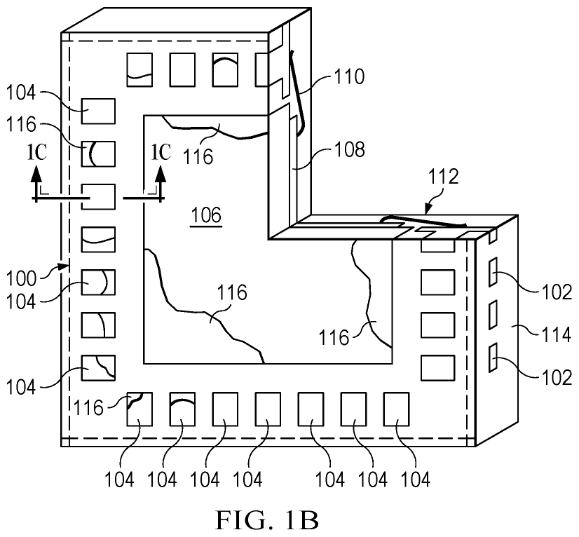

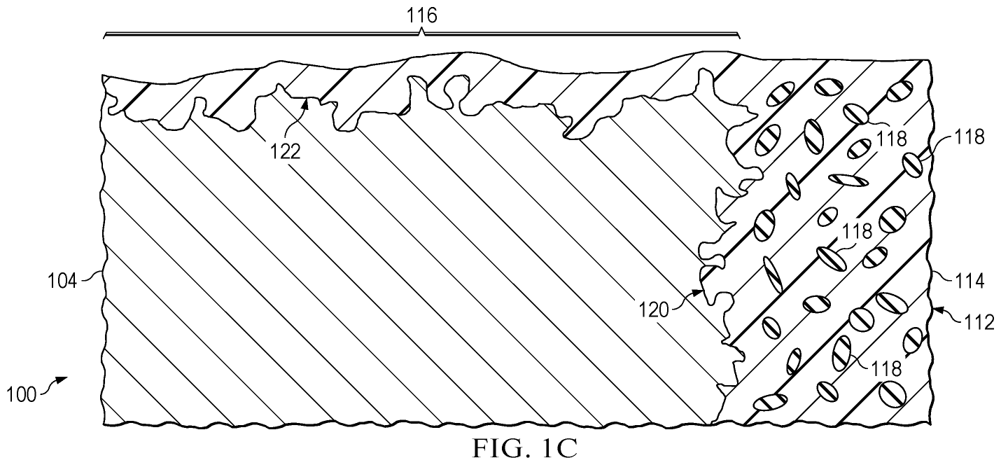

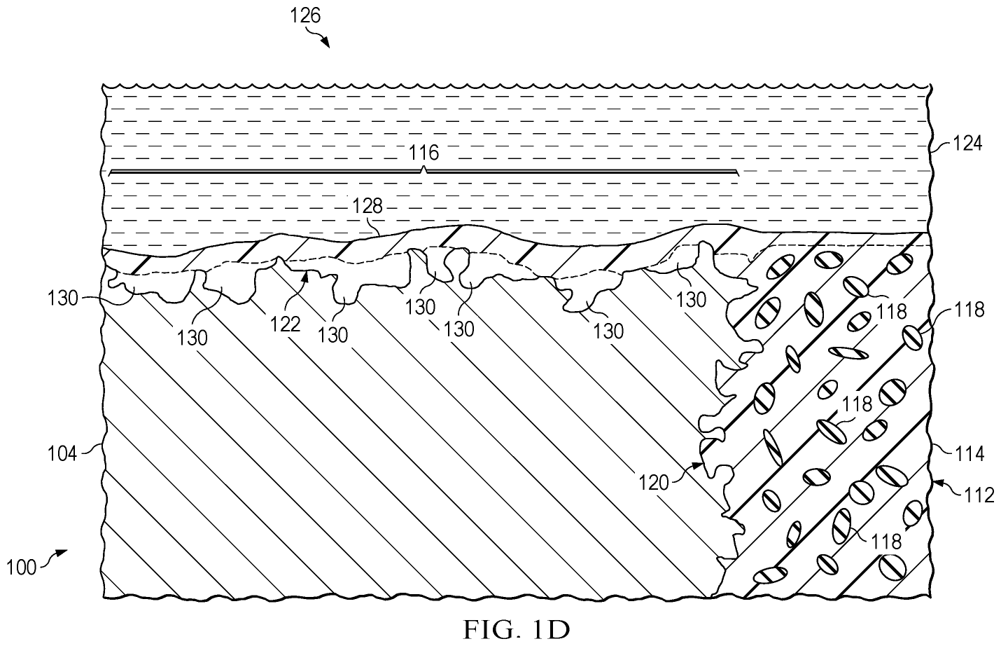

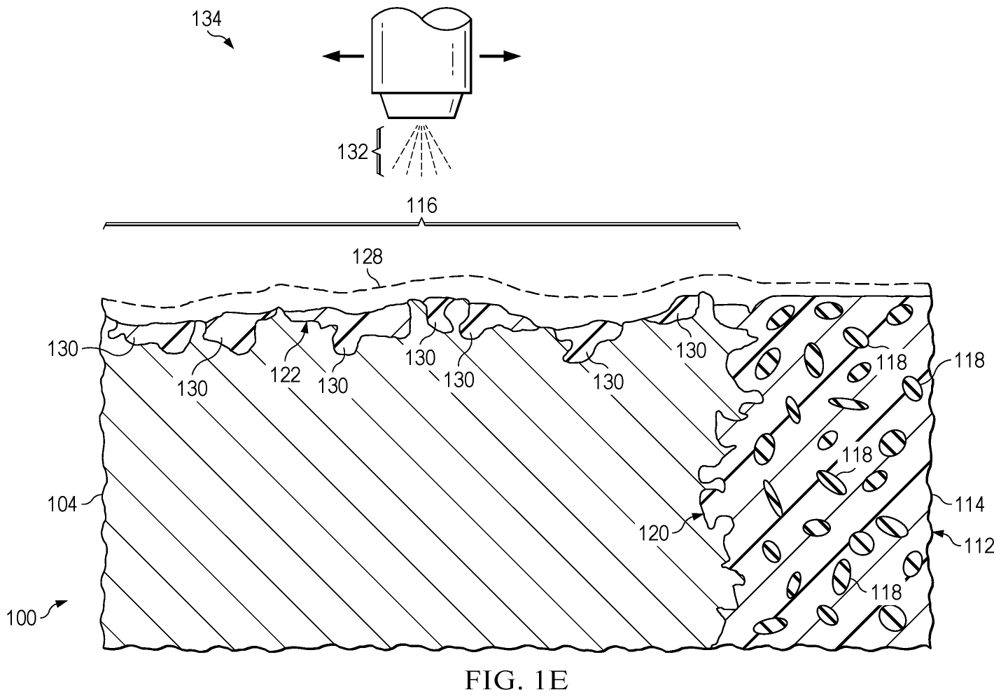

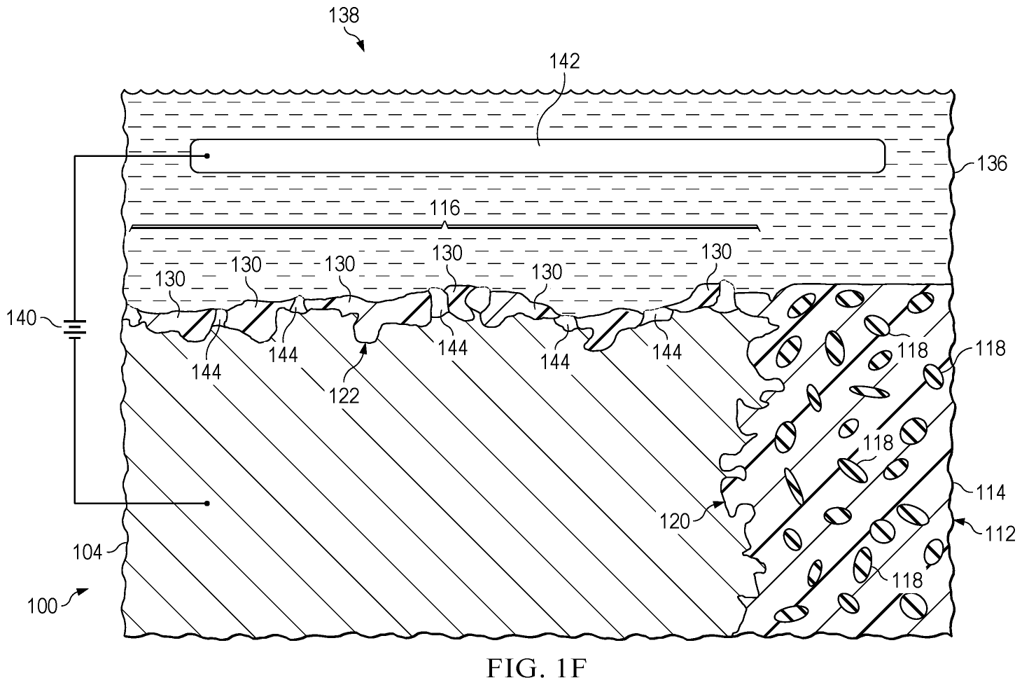

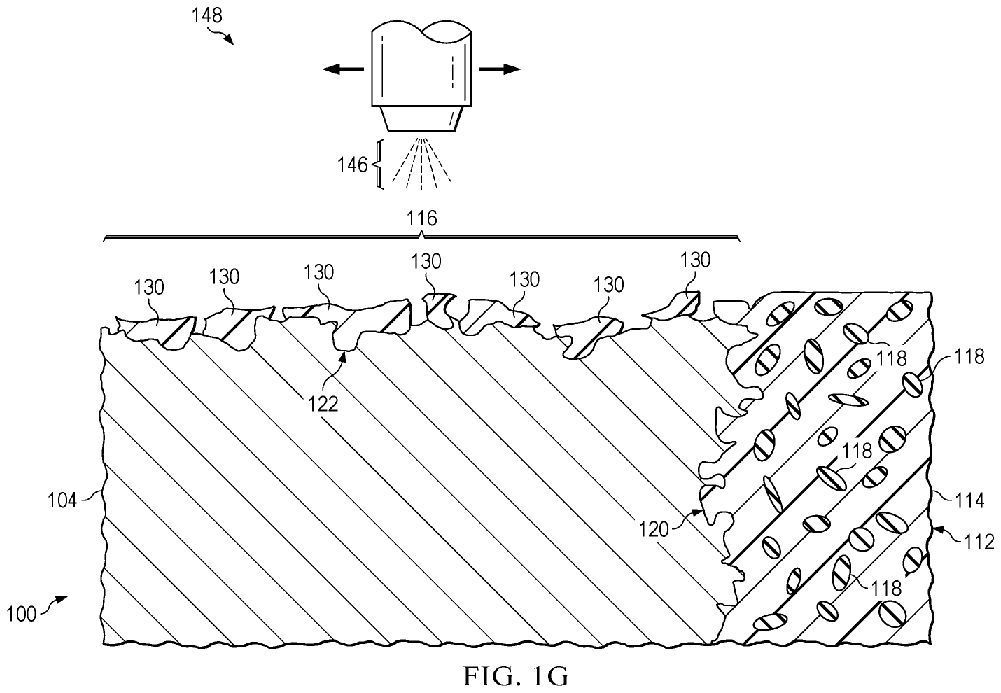

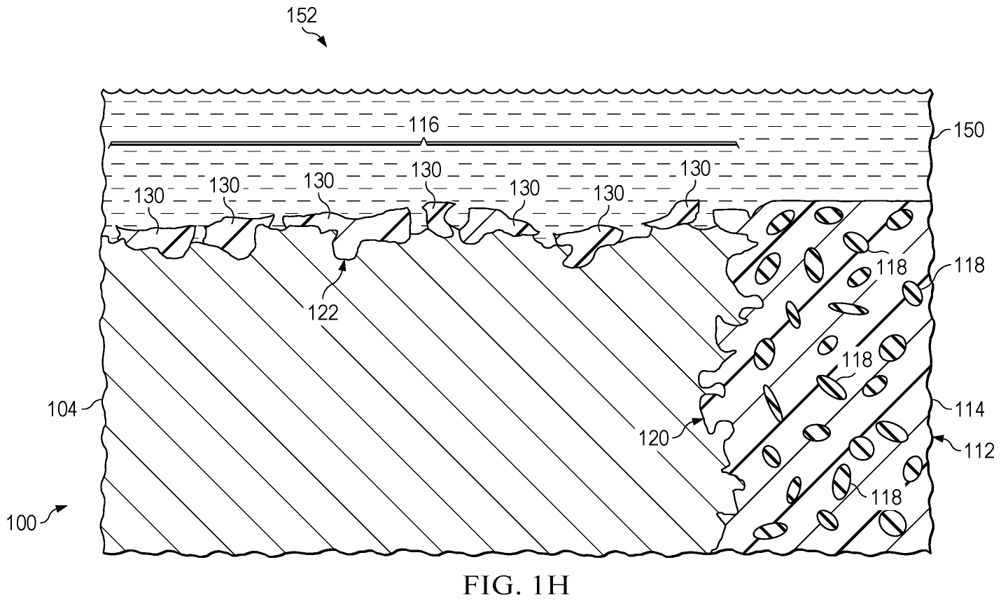

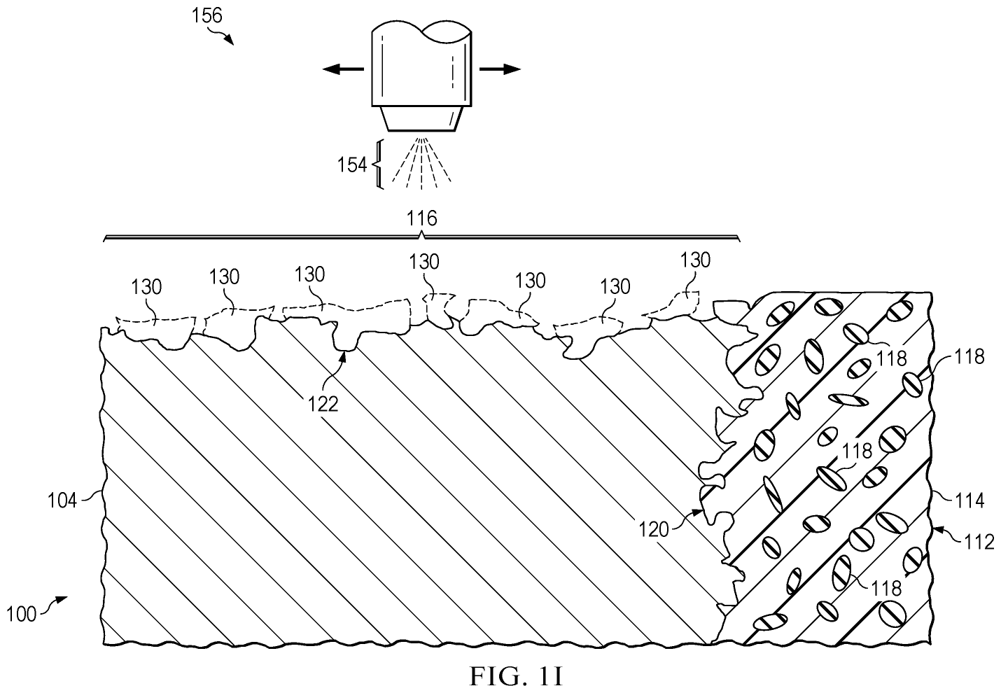

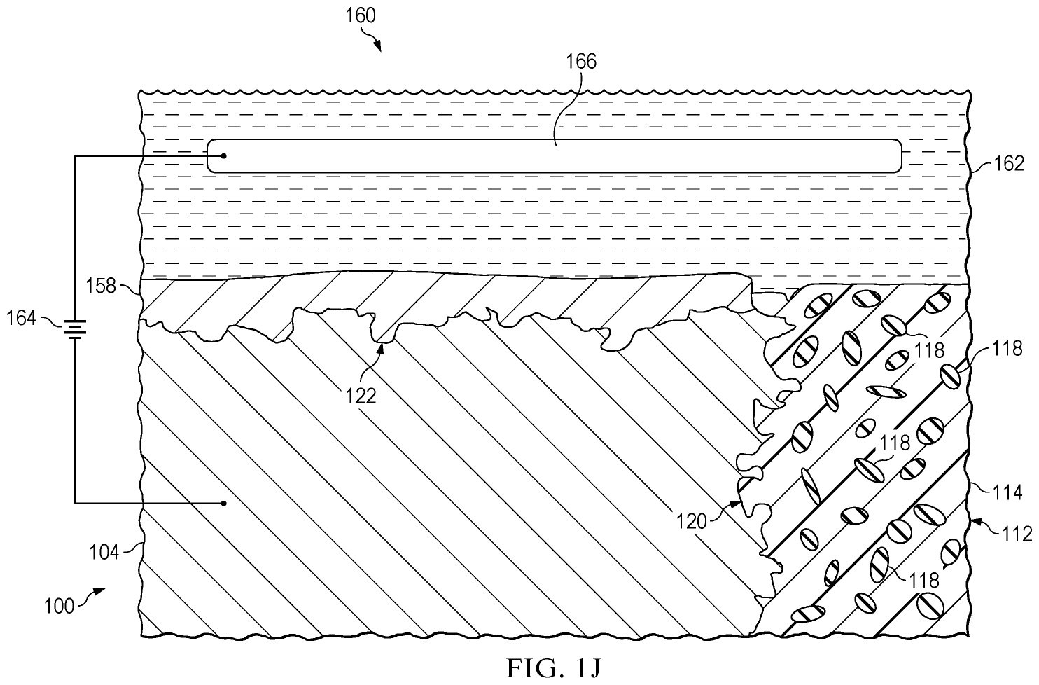

FIG. 1A through FIG. 1K are perspectives and cross sections of an example semiconductor package, depicted in stages of an example method of formation. Referring to FIG. 1A and FIG. 1B, which are perspective views, the semiconductor package 100 is formed with additional semiconductor packages 100a on a lead frame 102. The semiconductor package 100 includes leads 104, which are portions of the lead frame 102, and may include a die pad 106 of the lead frame 102. The leads 104 and the die pad 106 may include primarily copper, by way of example. The additional semiconductor packages 100a include additional leads 104a, which are portions of the lead frame 102, and may include additional die pads 106a of the lead frame 102. The semiconductor package 100 may have a quad flat no-lead (QFN) configuration, as depicted in FIG. 1A and FIG. 1B.

A semiconductor die 108 is electrically connected to at least some of the leads 104. The semiconductor die 108 may be electrically connected to the leads 104 through wire bonds 110, as indicated in FIG. 1B. Alternatively, the semiconductor die 108 may be electrically connected to the leads 104 through other types of electrical connections, such as solder bumps or pillars. Other semiconductor die, not specifically shown, are electrically connected to at least some of the additional leads 104a in each of the additional semiconductor packages 100a. The semiconductor die 108 may be attached to the die pad 106, if present.

An encapsulation material 112 is formed on the semiconductor die 108 and the leads 104, and on the additional semiconductor die and the additional leads 104a in each of the additional semiconductor packages 100a. The encapsulation material 112 includes a polymeric material 114. The polymeric material 114 may include primarily epoxy. Alternatively, the polymeric material 114 may include primarily benzocyclobutene (BCB). Other polymeric compositions for the polymeric material 114 are within the scope of this example.

A surface of each of the leads 104 and 104a is divided into an encapsulated surface portion and an exterior surface portion. The encapsulation material 112 is formed on the encapsulated surface portion of each of the leads 104 and 104a. The leads 104 and 104a may be roughened, by etching or by plating bumps, which may improve adhesion of the polymeric material 114 of the encapsulation material 112 to the leads 104 and 104a. A portion of the polymeric material 114 may undesirably extend onto some of the exterior surface portions of the leads 104 and 104a, forming mold flash 116, as depicted in FIG. 1A and FIG. 1B.

Referring to FIG. 1C, which is a cross section of one of the leads 104, the encapsulation material 112 may include particles 118 of electrically non-conductive inorganic material, such as silicon dioxide or aluminum oxide, to reduce a thermal expansion coefficient of the encapsulation material 112. The encapsulation material 112 contacts the encapsulated surface portion 120 of the lead 104. The mold flash 116 extends over, and contacts, the exterior surface portion 122 of the lead 104. FIG. 1C depicts the encapsulated surface portion 120 and the exterior surface portion 122 of the lead 104 as having been roughened by an etch process. Other methods of roughening the lead 104 are within the scope of this example. At this point in formation of the semiconductor package 100, a surface roughness of the encapsulated surface portion 120 and a surface roughness of the exterior surface portion 122 may be substantially equal, within tolerances encountered in formation of lead frames, as a result of both of the surface portions 120 and 122 being formed concurrently. If the lead 104 is roughened, both of the surface portions 120 and 122 are roughened substantially equally. The surface roughness of the surface portions 120 and 122 may be 1 micron to 8 microns, by way of example.

Referring to FIG. 1D, the semiconductor package 100 is exposed to a first descaling solution 124 which contacts the mold flash 116, in a first chemical deflash process 126. The first descaling solution 124 may be implemented as an aqueous buffered alkaline solution with a pH value of 8.0 to 9.0, by way of example. The first descaling solution 124 may have a temperature of 60° C. to 100° C. Other implementations for the first descaling solution 124, such as organic solvents, are within the scope of this example. The organic solvents may include solvents which soften or dissolve epoxy, such as toluene, acetone, n-methlypyrollidone (NMP), methyl-ethylketone (MEK), or a combination thereof.

The first descaling solution 124 may soften and/or swell a first portion 128 of the mold flash 116, leaving a remaining portion 130 of the mold flash 116 attached to the exterior surface portion 122 of the lead 104. In versions of this example in which the first descaling solution 124 is implemented as an aqueous buffered alkaline solution, carbon-oxygen bonds in the mold flash 116 may be broken, and hydroxyl groups may be attached to the corresponding carbon atoms, swelling the mold flash 116 while reducing adhesion of the mold flash 116 to the lead 104. In versions of this example in which the first descaling solution 124 is implemented as one or more organic solvents, organic molecules of the organic solvents may diffuse between polymer molecules of the mold flash 116, similarly swelling the mold flash 116 while reducing adhesion of the mold flash 116 to the lead 104.

The first chemical deflash process 126 may be performed until the first portion 128 of the mold flash 116 extends to the exterior surface portion 122 of the lead 104. The first chemical deflash process 126 may be performed for 50 seconds to 100 seconds, by way of example.

Referring to FIG. 1E, the semiconductor package 100 is exposed to a first fluid spray 132, which removes the first portion 128 of the mold flash 116, in a first rinse process 134. The first fluid spray 132 may be implemented as a water spray at a pressure of 3 bar to 10 bar, having a fluid temperature of 50° C. to 70° C. The semiconductor package 100 may be exposed to the first fluid spray 132 for 5 seconds to 30 seconds, by way of example. The pressure, fluid temperature, and exposure time may be adjusted to remove the first portion 128 of the mold flash 116 without reducing adhesion of the encapsulation material 112 to the encapsulated surface portion 120 of the lead 104. After the first rinse process 134 is completed, areas of the lead 104 at the exterior surface portion 122 are exposed by the remaining portion 130 of the mold flash 116.

Referring to FIG. 1F, the semiconductor package 100 is exposed to an electrolytic solution 136 as part of a selective descaling process 138. The electrolytic solution 136 of this example has a pH value of 1.0 to 4.0. The electrolytic solution 136 may include polyethylene glycol as an inhibitor. Other inhibitors may be used. The electrolytic solution 136 may have a temperature of 28° C. to 35° C., for example. A positive electric potential is applied to the lead 104 with respect to the electrolytic solution 136. The positive electric potential may be 1.4 volts to 2.0 volts, for example. The positive electric potential may be provided by a constant voltage source 140 with a positive terminal connected to the lead 104 and a negative terminal connected to a cathode 142 in the electrolytic solution 136. The cathode 142 may include one or more metals such as stainless steel or platinum. The constant voltage source 140 may supply several amperes, for example 3 amperes to 5 amperes, depending on the total exposed area on the leads 104 and 104a and the die pads 106 and 106a, shown in FIG. 1A.

A deplated portion 144 of the lead 104 is removed by the selective descaling process 138 at the exterior surface portion 122 of the lead 104 where exposed by the remaining portion 130 of the mold flash 116. The deplated portion 144 of the lead 104 is removed by the current flowing from the lead 104 through the electrolytic solution 136 to the cathode 142. The selective descaling process 138 may remove, for example, 1 micron to 5 microns of the lead 104, where exposed by the remaining portion 130 of the mold flash 116. The inhibitor in the electrolytic solution 136 may advantageously provide more uniform removal of the deplated portion 144 across the lead 104 compared to electrolytic solutions without an inhibitor. Removal of the deplated portion 144 of the lead 104 may advantageously reduce adhesion of the remaining portion 130 of the mold flash 116 to the lead 104 by reducing a contact area between the remaining portion 130 and the exterior surface portion 122 of the lead 104. The selective descaling process 138 may be performed for 10 seconds to 20 seconds, by way of example, depending on the amount of the lead 104 removed, to sufficiently reduce adhesion of the remaining portion 130 of the mold flash 116 to the lead 104.

Removal of the deplated portion 144 of the lead 104 by the selective descaling process 138 reduces a surface roughness of the exterior surface portion 122 of the lead 104. Peaks and protrusions of the lead 104 at the exterior surface portion 122 may be selectively eroded, referred to as anodic leveling. After the selective descaling process 138 is completed, the surface roughness of the exterior surface portion 122 of the lead 104 is less than a surface roughness of the encapsulated surface portion 120 of the lead 104. In one version of this example, the surface roughness of the exterior surface portion 122 may be less than half the surface roughness of the encapsulated surface portion 120.

The selective descaling process 138 may be performed in line with the first chemical deflash process 126 of FIG. 1D and the first rinse process 134 of FIG. 1E, advantageously reducing cost and cycle time for removing the mold flash 116. In this context, the lead frame 102 of FIG. 1A, with the semiconductor package 100 and the additional semiconductor packages 100a of FIG. 1A, may be transported from the first chemical deflash process 126 to the first rinse process 134 and on to the selective descaling process 138 by a transport mechanism connected to the equipment performing the first chemical deflash process 126, the first rinse process 134, and the selective descaling process 138.

Referring to FIG. 1G, the semiconductor package 100 is exposed to a second fluid spray 146, in a second rinse process 148, which rinses the semiconductor package 100 and removes any remaining fluid of the electrolytic solution 136 of FIG. 1F. The second fluid spray 146 may also remove any loose pieces of the mold flash 116. The second fluid spray 146 may be implemented as a water spray having similar pressure, temperature, and exposure time to the first fluid spray 132 of FIG. 1E, by way of example. The pressure, fluid temperature, and exposure time of the second fluid spray 146 may be adjusted to reduce degradation of the encapsulation material 112. After the second rinse process 148 is completed, a majority of the remaining portion 130 of the mold flash 116 may still be present on the lead 104 at the exterior surface portion 122.

Referring to FIG. 1H, the semiconductor package 100 is exposed to a second descaling solution 150 which contacts the remaining portion 130 of the mold flash 116, in a second chemical deflash process 152. The second descaling solution 150 may have similar composition, pH value, and temperature to the first descaling solution 124 of FIG. 1D. The second descaling solution 150 may soften and/or swell the remaining portion 130 of the mold flash 116. The second chemical deflash process 152 may be performed until the remaining portion 130 of the mold flash 116 is loosened from the exterior surface portion 122 of the lead 104. The second chemical deflash process 152 may be performed for 50 seconds to 100 seconds, by way of example.

Referring to FIG. 1I, the semiconductor package 100 is exposed to a third fluid spray 154, in a third rinse process 156, which removes the remaining portion 130 of the mold flash 116. The third fluid spray 154 may be implemented as a water spray at a pressure of 150 bar to 500 bar, having a fluid temperature of 20° C. to 30° C. The semiconductor package 100 may be exposed to the third fluid spray 154 for 30 seconds to 90 seconds, by way of example. The pressure, fluid temperature, and exposure time of the third fluid spray 154 may be adjusted to remove the remaining portion 130 of the mold flash 116 without reducing adhesion of the encapsulation material 112 to the encapsulated surface portion 120 of the lead 104.

The second rinse process 148 of FIG. 1G, the second chemical deflash process 152 of FIG. 1H, and the third rinse process 156 may be performed in line with the first chemical deflash process 126 of FIG. 1D, the first rinse process 134 of FIG. 1E, and the selective descaling process 138 of FIG. 1F, advantageously reducing cost and cycle time for removing the mold flash 116. After the third rinse process 156 is completed, the semiconductor package 100 and the additional semiconductor packages 100a may be exposed to a copper etching solution, not specifically shown, as part of a descaling process to remove oxides from the exterior surface portion 122 of the lead 104. The descaling process may be performed in line with the third rinse process 156.

Referring to FIG. 1J, a solderable metal layer 158 is formed, in this example, by a plating process 160 on the exterior surface portion 122 of the lead 104. The solderable metal layer 158 is concurrently formed on all the leads 104 and the die pad 106 of FIG. 1A and FIG. 1B, if present, and on the additional leads 104a and the additional die pads 106a, if present, of FIG. 1A. The solderable metal layer 158 may include tin, nickel, silver, or a combination thereof, by way of example. In one version of this example, the solderable metal layer 158 may include primarily tin. The plating process 160 may use a plating bath 162. The plating process 160 may be implemented as an electroplating process 160 using a power supply 164 to provide a negative bias potential to the lead 104 and a positive bias to a metal anode 166 in the plating bath 162. The metal anode 166 includes a solderable metal, such as tin. The plating process 160 may be performed in line with the descaling process. Performing the first chemical deflash process 126 of FIG. 1D, the first rinse process 134 of FIG. 1E, the selective descaling process 138 of FIG. 1F, the second rinse process 148 of FIG. 1G, the second chemical deflash process 152 of FIG. 1H, the third rinse process 156 of FIG. 1I, the descaling process, and the plating process 160 inline may advantageously reduce the cost and cycle time for forming the semiconductor package 100.

FIG. 1K depicts the semiconductor package 100 after the plating process 160 of FIG. 1J, and after the semiconductor package 100 is singulated from the additional semiconductor packages 100a of FIG. 1A. Removal of the mold flash 116 of FIG. 1C may advantageously enable the solderable metal layer 158 to provide a reliable solder joint to a circuit board at the exterior surface portions of the leads 104 and die pad 106 of FIG. 1B. The semiconductor package 100 may be singulated by a saw process, for example.

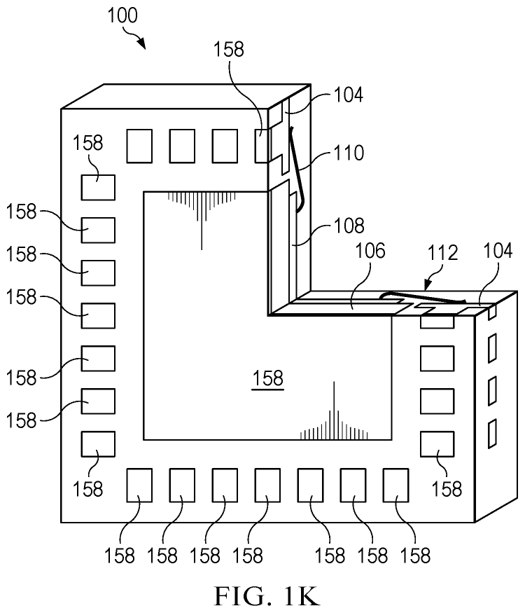

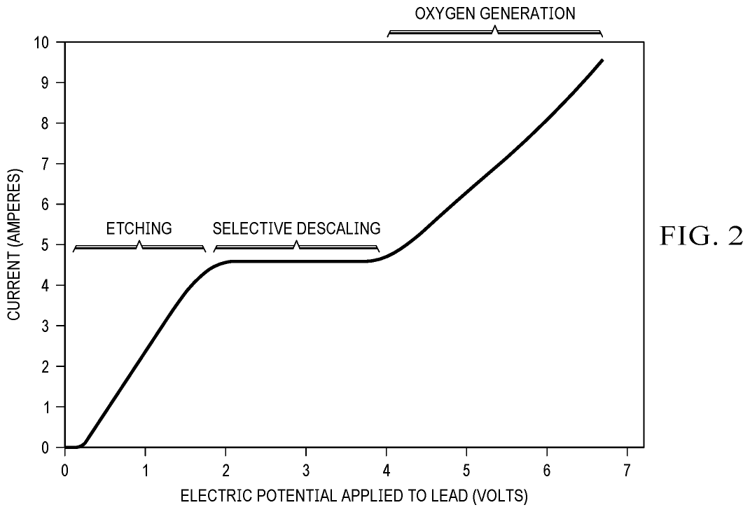

FIG. 2 is a current voltage graph for an example selective descaling process, for example, the selective descaling process 138 as disclosed in reference to FIG. 1F. Elements of the selective descaling process discussed in reference to FIG. 2 are to be found in the disclosure in reference to FIG. 1A through FIG. 1K. The horizontal axis is the electric potential applied to the lead 104, with respect to the cathode 142 in the electrolytic solution 136, of FIG. 1F. The vertical axis is the current from the lead 104 through the electrolytic solution 136 to the cathode 142.

The current voltage graph has three different ranges: an etching range, a selective descaling range, and an oxygen generation range. In the etching range, labeled in FIG. 2 as “ETCHING,” the electric potential extends from a few millivolts to approximately 0.7 volts, depending on compositions and concentrations of reagents in the electrolytic solution 136 and the pH value of the electrolytic solution 136. The etching range is characterized by the current increasing as the electric potential increases. In the etching range, etching of the lead 104 occurs, mainly at grain boundaries. Furthermore, the etch rate depends on the current density, which varies with the electric potential and the exposed area of the lead 104, making control of the metal removal rate difficult.

In the selective descaling range, labeled in FIG. 2 as “SELECTIVE DESCALING,” the electric potential extends from 1.0 volts to 2.5 volts, and is characterized by a constant current, within 20 percent of an average value of the current over 1.0 volts to 2.5 volts. In the selective descaling range, a viscous liquid layer may be formed on the exterior surface portion 122 of the lead 104, where exposed by the remaining portion 130 of the mold flash 116, due to continuously dissolving copper ions at high concentrations in form of aqueous cupric salts. Transport of the copper ions away from the lead 104 is limited by diffusion processes through the viscous layer that produces the constant current in the selective descaling range. Polyethylene glycol in the electrolytic solution 136 may increase the viscosity of the viscous liquid layer, improving uniformity of metal removal across the lead 104. Projections of the lead 104, where exposed by the remaining portion 130 of the mold flash 116, protrude further into the viscous liquid layer, extending to regions with lower ionic concentrations resulting in more effective dissolution and faster removal of copper from the projections.

In the oxygen generation range, labeled “OXYGEN GENERATION,” in FIG. 2, the electric potential extends above 2.5 volts. In the oxygen generation range, molecular oxygen (O₂) is formed at the exterior surface portion 122 of the lead 104, where exposed by the remaining portion 130 of the mold flash 116, by oxidation of hydroxyl ions. Bubbles of oxygen that may be trapped on the exterior surface portion 122 of the lead 104, may undesirably result in non-uniform removal of copper from the exterior surface portion 122 of the lead 104.

Thus, the selective descaling process 138 may be performed in the selective descaling range by adjusting the electric potential to a value in the selective descaling range. Operating in the selective descaling range may advantageously remove metal from the exterior surface portion 122 of the lead 104 at a controllable rate and reduce adhesion of the remaining portion 130 of the mold flash 116 to the lead 104. Operating in the selective descaling range may avoid adverse side effects such as the variable and non-uniform removal rates in the etching range and the oxygen generation range.

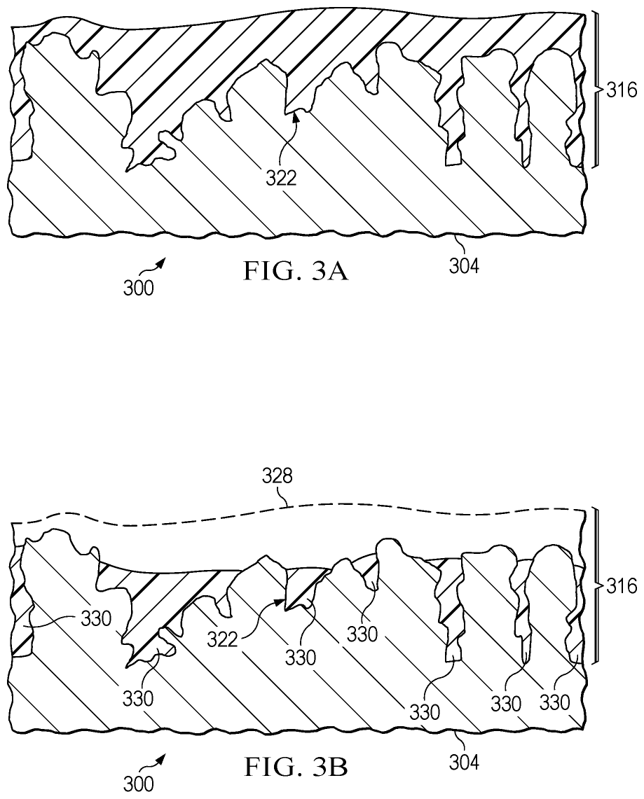

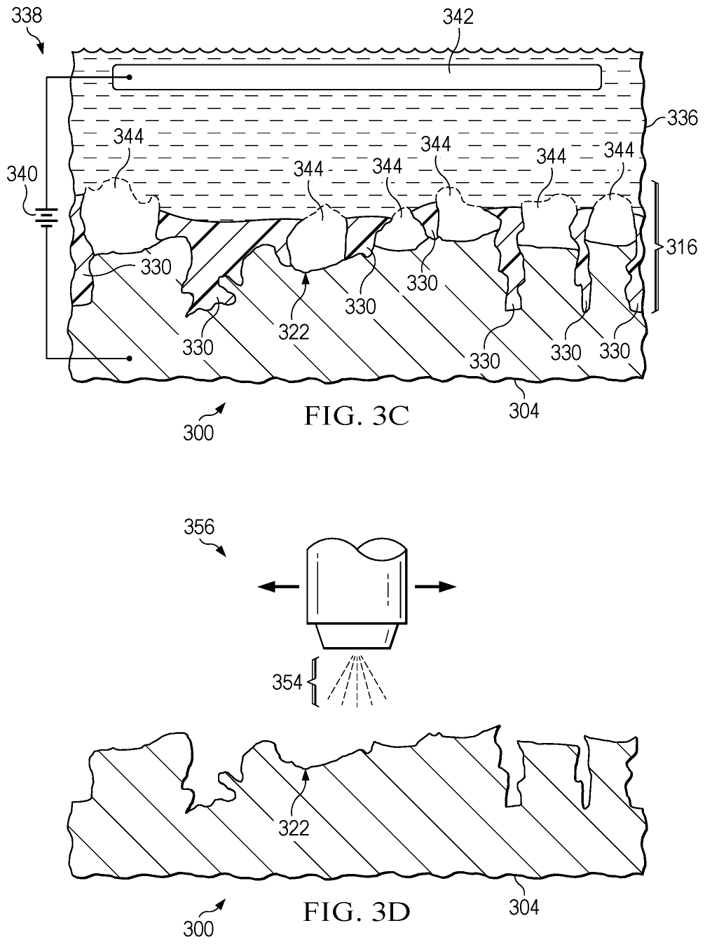

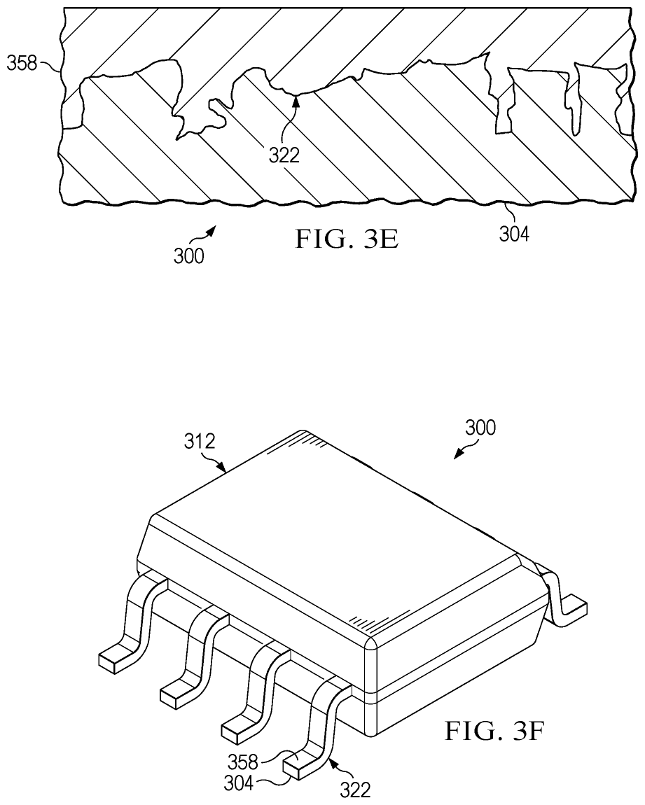

FIG. 3A through FIG. 3F are cross sections and a perspective of another example semiconductor package, depicted in stages of another example method of formation. Referring to FIG. 3A, which is a cross section of the semiconductor package 300 through a lead 304, mold flash 316 is present on an exterior surface portion 322 of the lead 304. FIG. 3A depicts the exterior surface portion 322 of the lead 304 as having been roughened by a plating process.

Referring to FIG. 3B, a first portion 328 of the mold flash 316 is removed, leaving a remaining portion 330 of the mold flash 316 attached to the exterior surface portion 322 of the lead 304. Areas of the lead 304 at the exterior surface portion 322 are exposed by the remaining portion 330 of the mold flash 316. The first portion 328 of the mold flash 316 may be removed by a combination of a chemical deflash process and a fluid spray. The first portion 328 of the mold flash 316 may be removed by an atmospheric plasma which directs oxygen radicals onto the mold flash 316. The first portion 328 of the mold flash 316 may be removed by laser ablation using an ultraviolet laser. The laser may be focused on the mold flash 316, avoiding encapsulated areas of the semiconductor package 300. The first portion 328 of the mold flash 316 may be removed by micro-abrasive blasting, which uses a micro-particle abrasive media and small nozzles to generate a precise abrasive jet. The abrasive jet may be raster scanned across the leads, avoiding encapsulated areas of the semiconductor package 300. Other methods for removing the first portion 328 of the mold flash 316 are within the scope of this example.

Referring to FIG. 3C, a selective descaling process 338 removes a deplated portion 344 of the lead 304. The selective descaling process 338 includes exposing the exterior surface portion 322 of the lead 304 to an electrolytic solution 336, as disclosed in reference to FIG. 1F. A positive electric potential, provided by a power supply 340, is applied to the lead 304 with respect to a cathode 342 in the electrolytic solution 336. Removal of the deplated portion 344 of the lead 304 reduces a contact area between the remaining portion 330 of the mold flash 316 and the lead 304, advantageously adhesion of the remaining portion 330 of the mold flash 316 to the lead 304.

Referring to FIG. 3D, the semiconductor package 300 is exposed to a rinse process 356 which removes the remaining portion 330 of the mold flash 316 of FIG. 3C. The rinse process 356 of this example uses a fluid spray 354, which may be implemented as a water spray, as disclosed in reference to the third rinse process 156 of FIG. 1I. Alternatively, the fluid spray 354 may be implemented as a solvent spray, a cryogenic spray using supercritical carbon dioxide or liquid nitrogen. Other implementations of the fluid spray 354 are within the scope of this example.

Referring to FIG. 3E, a solderable metal layer 358 is formed on the exterior surface portion 322 of the lead 304. The solderable metal layer 358 may include one or more layers of tin, silver, nickel, gold, palladium, bismuth, or a combination thereof. In some versions of this example, the solderable metal layer 358 may be formed by an electroplating process or an electroless plating process. In other versions, the solderable metal layer 358 may be formed by screen printing solder paste onto the lead 304, followed by curing and reflowing the solder paste to form a solder layer. In further versions, the solderable metal layer 358 may be formed by a dip soldering process or a wave soldering process. Other methods of forming the solderable metal layer 358 are within the scope of this example.

FIG. 3F depicts the semiconductor package 300 after singulation from a lead frame, not specifically shown. In one version of this example, the lead 304 may be formed into a gull wing shape for a small outline integrated circuit (SOIC) package, as depicted in FIG. 3F, or a small outline transistor (SOT) package. In other versions of this example, the lead 304 may be formed into a straight downward shape for a dual inline package (DIP), or formed to curve under an encapsulation material 312 for a J-lead package. The solderable metal layer 358 is on the exterior surface portion 322 of the lead 304, which is exposed by the encapsulation material 312. Removal of the mold flash 316 of FIG. 3A may advantageously enable the solderable metal layer 358 to provide a reliable solder joint to a circuit board at the exterior surface portions of the leads 304.

Various features of the examples disclosed herein may be combined in other manifestations of example semiconductor packages. For example, the semiconductor package 100 of FIG. 1K may be implemented as an SOIC package, an SOT package, a DIP, or a J-lead package, as described in reference to FIG. 3F. Similarly, the semiconductor package 300 of FIG. 3F may have a QFN configuration, as described in reference to FIG. 1A and FIG. 1B. The semiconductor package 100 may be formed by the process described in reference to FIG. 3A through FIG. 3F. The semiconductor package 300 may be formed by the process described in reference to FIG. 1A through FIG. 1K.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and equivalents.

What is claimed is:

1. A method of forming a semiconductor package, comprising:
removing a first portion of a polymer material on an exterior surface portion of a lead of the semiconductor package, wherein areas of the lead at the exterior surface portion are exposed by a remaining portion of the polymer material;
removing a portion of the lead where exposed by the remaining portion of the polymer material, by an electrolytic process, the electrolytic process including biasing the lead to a positive potential with respect to an electrolytic solution contacting the exterior surface portion of the lead; and
removing the remaining portion of the polymer material from the exterior surface portion.

2. The method of claim 1, wherein the positive potential is 1.4 volts to 2.5 volts.

3. The method of claim 1, wherein the lead includes primarily copper.

4. The method of claim 1, wherein the polymer material includes primarily epoxy.

5. The method of claim 1, wherein the portion of the lead removed is 1 micron to 5 microns at the exterior surface portion.

6. The method of claim 1, wherein removing the remaining portion of the polymer material uses an alkaline solution followed by a fluid spray.

7. A method of forming a semiconductor package, comprising:
exposing the semiconductor package to a first descaling solution, wherein the semiconductor package includes:
a lead having a surface with an exterior surface portion and an encapsulated surface portion;
a semiconductor die electrically connected to the encapsulated surface portion of the lead; and
an encapsulation material including a polymer material, the encapsulation material contacting the semiconductor die and contacting the encapsulated surface portion of the lead;
exposing the semiconductor package to a first fluid spray;
exposing the semiconductor package to an electrolytic solution while applying a positive electric potential to the lead with respect to the electrolytic solution, wherein a portion of the lead is removed at the exterior surface portion where exposed by the polymer material;
exposing the semiconductor package to a second fluid spray;
exposing the semiconductor package to a second descaling solution; and
exposing the semiconductor package to a third fluid spray.

8. The method of claim 7, wherein the positive electric potential is 1.4 volts to 2.5 volts.

9. The method of claim 7, wherein the electrolytic solution has a pH value of 1.0 to 4.0.

10. The method of claim 7, wherein the first descaling solution and the second descaling solution are aqueous alkaline solutions.

11. The method of claim 7, wherein the polymer material includes primarily epoxy.

12. The method of claim 7, wherein the portion of the lead removed is 1 micron to 5 microns at the exterior surface portion.

13. The method of claim 7, wherein the third fluid spray uses water pressurized to 150 bar to 500 bar.

14. The method of claim 7, wherein the first fluid spray uses water pressurized to 3 bar to 10 bar.

15. The method of claim 7, further including plating a solderable metal on the exterior surface portion of the lead.

16. A semiconductor package, comprising:
a lead having a surface with an exterior surface portion and an encapsulated surface portion, wherein the lead has a higher surface roughness at the encapsulated surface portion than at the exterior surface portion;
a solderable metal layer on the exterior surface portion of the lead;
a semiconductor die electrically connected to the encapsulated surface portion of the lead; and
an encapsulation material including a polymer material, the encapsulation material contacting the semiconductor die and contacting the encapsulated surface portion of the lead, wherein the solderable metal layer is exposed at an exterior of the semiconductor package.

17. The semiconductor package of claim 16, wherein a surface roughness at the encapsulated surface portion is 1 micron to 8 microns.

18. The semiconductor package of claim 16, wherein the lead includes primarily copper.

19. The semiconductor package of claim 16, wherein the polymer material includes primarily epoxy.

20. The semiconductor package of claim 16, wherein the solderable metal layer includes primarily tin.
